(19) United States
(12) Patent Application Publication
(10) Pub. No.: US 2016/0247950 A1
(43) Pub. Date: Aug. 25, 2016

(54) SOLAR CELL ELEMENT AND METHOD FOR MANUFACTURING SOLAR CELL ELEMENT

(71) Applicant: KYOCERA CORPORATION, Kyoto (JP)

(72) Inventors: Naoya KOBAMOTO, Kobe-shi (JP); Tomonari Sakamoto, Higashiomi-shi (JP)

(21) Appl. No.: 15/054,007

(22) Filed: Feb. 25, 2016

Related U.S. Application Data
(63) Continuation of application No. PCT/JP2014/072802, filed on Aug. 29, 2014.

(30) Foreign Application Priority Data
Aug. 30, 2013 (JP) 2013-180118

(51) Int. Cl. H01L 31/0224; H01L 31/0236; H01L 31/0216; H01L 31/18

(52) U.S. Cl. CPC H01L 31/022466; H01L 31/1884; H01L 31/02366; H01L 31/02168

(57) ABSTRACT

In a solar cell element including a silicon substrate that includes a p-type semiconductor region in a surface thereof and an electrode that is located on the p-type semiconductor region and based on aluminum, the electrode includes a glass component containing vanadium oxide, tellurium oxide, and boron oxide, the glass component having a vanadium oxide content smaller than the sum of a tellurium oxide and a boron oxide content. Alternatively, the electrode includes a glass component containing vanadium oxide, tellurium oxide, and boron oxide, the glass component containing 5 to 33 parts by mass of vanadium oxide, 4 to 30 parts by mass of tellurium oxide, and 4 to 18 parts by mass of boron oxide based on 100 parts by mass of the glass component.

### CROSS-REFERENCE TO RELATED APPLICATIONS

The present application is a continuation of International Application No. PCT/JP2014/072802, filed on Aug. 29, 2014, which claims the benefit of Japanese Patent Application No. 2013-180118, filed on Aug. 30, 2013. The contents of these applications are incorporated herein by reference in their entirety.

### TECHNICAL FIELD

The present invention relates to a solar cell element and a method for manufacturing the same.

### BACKGROUND ART

In general, a solar cell element including a silicon substrate as a semiconductor substrate has the p-n junction structure in which the light receiving surface of the silicon substrate of one conductivity type is provided with a reverse-conductivity-type layer formed therein. Further, the solar cell element includes a p-type electrode electrically connected with a p-type silicon region and an n-type electrode electrically connected with an n-type silicon region.

An aluminum-based electrode has been known as the above-mentioned p-type electrode. (See, for example, Japanese Patent Application Laid-Open No. 2003-223813, Japanese Patent Application Laid-Open No. 2012-218982, and Japanese Patent Application Laid-Open No. 2013-168369.)

### SUMMARY OF INVENTION

### Problems to be Solved by the Invention

For example, electrodes for use in a solar cell element need to be strongly adhesive to the semiconductor substrate on which the electrodes are formed and an increase in the warpage of the semiconductor substrate after the formation of electrodes needs to be small. However, the characteristics of the electrodes are likely to be affected by the structure, such as the surface shape, of the semiconductor substrate on which the electrodes are formed.

The present invention therefore has been made in view of these problems, and objects thereof are, in particular, to provide a solar cell element in which electrodes are strongly adhesive to the semiconductor substrate and an increase in the warpage of a silicon substrate after the formation of electrodes is small, and to provide a method for manufacturing the same.

### Means to Solve the Problems

A solar cell element according to one aspect of the present invention includes a silicon substrate including a p-type semiconductor region in a surface thereof and an electrode that is located on the p-type semiconductor region and based on aluminum. The electrode includes a glass component containing vanadium oxide, tellurium oxide, and boron oxide. The glass component has a vanadium oxide content smaller than a sum of a tellurium oxide content and a boron oxide content.

A solar cell element according to another aspect of the present invention includes a silicon substrate including a p-type semiconductor region in a surface thereof and an electrode that is located on the p-type semiconductor region and based on aluminum. The electrode includes a glass component containing vanadium oxide, tellurium oxide, and boron oxide. The glass component contains 5 to 33 parts by mass of vanadium oxide, 4 to 30 parts by mass of tellurium oxide, and 4 to 18 parts by mass of boron oxide based on 100 parts by mass of the glass component.

A method for manufacturing a solar cell element according to one aspect of the present invention is a method for manufacturing a solar cell element including a silicon substrate that includes a p-type semiconductor region in a surface thereof and an electrode that is located on the p-type semiconductor region and based on aluminum. The method includes a printing step of printing a conductive paste on the p-type semiconductor region of the silicon substrate and an electrode forming step of forming the electrode on the p-type semiconductor region of the silicon substrate by firing the conductive paste. The conductive paste includes a glass component, aluminum-based powder, and an organic vehicle. The glass component contains vanadium oxide, tellurium oxide, and boron oxide. The glass component has a vanadium oxide content smaller than a sum of a tellurium oxide content and a boron oxide content.

A method for manufacturing a solar cell element according to another aspect of the present invention is a method for manufacturing a solar cell element including a silicon substrate that includes a p-type semiconductor region in a surface thereof and an electrode that is located on the p-type semiconductor region and based on aluminum. The method includes a printing step of printing a conductive paste on the p-type semiconductor region of the silicon substrate and an electrode forming step of forming the electrode on the p-type semiconductor region of the silicon substrate by firing the conductive paste. The conductive paste includes a glass component, aluminum-based powder, and an organic vehicle. The glass component contains vanadium oxide, tellurium oxide, and boron oxide. The glass component contains 5 to 33 parts by mass of vanadium oxide, 4 to 30 parts by mass of tellurium oxide, and 4 to 18 parts by mass of boron oxide based on 100 parts by mass of the glass component.

### Effects of the Invention

The solar cell element having the above-mentioned configuration and the method for manufacturing the same can provide a solar cell element in which high conversion efficiency is maintained, an increase in the warpage of the substrate after the formation of electrodes is prevented, and the electrodes have improved adhesion to the substrate.

The solar cell element having the above-mentioned configuration and the method for manufacturing the same can provide an solar cell element that can achieve excellent electrode characteristics that are less likely to be affected by the structure of the electrode formation surface of the silicon substrate in a case where the electrode formation surface has a texture, an anti-reflection layer is formed thereon, or the like.

### BRIEF DESCRIPTION OF DRAWINGS

FIG. 1 is a plan view of an example of a solar cell element according to one embodiment of the present invention when seen from a light receiving surface side.

FIG. 2 is a plan view of an example of the solar cell element according to one embodiment of the present invention when seen from a non-light receiving surface side.

FIG. 3 is a cross-sectional view of a portion taken along an alternate long and short dash line part of the line K-K in FIG. 1.

### DESCRIPTION OF EMBODIMENTS

Embodiments of the present invention are described in detail with reference to the drawings. Note that the drawings are schematic illustrations, and thus, the sizes, the positional relation, and the like of the constituent components in each of the drawing may be changed as appropriate.

<Conductive Paste>

A conductive paste for electrodes included in the solar cell element according to the present embodiment includes, for example, aluminum powder based on aluminum, an organic vehicle, and a glass component containing at least vanadium oxide, tellurium oxide, and boron oxide. The glass component has a vanadium oxide content smaller than the sum of a tellurium oxide content and a boron oxide content. The glass component of the conductive paste may contain 5 to 33 parts by mass of vanadium oxide, 4 to 30 parts by mass of tellurium oxide, and 4 to 18 parts by mass of boron oxide based on 100 parts by mass of the glass component.

The aluminum powder is the metal powder based on high-purity aluminum or the metal powder based on an aluminum-based alloy. The expression “-based (based on)” means that the amount of the relevant component present in the metal powder as a whole is 50% by mass or more, which holds true for the definition of the expression “-based (based on)” in the following description.

Although the aluminum powder is not required to have a particular shape, the powder may have a spherical shape, a flake shape, or the like. The particle diameter of the aluminum powder is selected as appropriate depending on the coating (printing) conditions and firing conditions for the conductive paste. The powder having an average particle diameter of about 0.1 to 10 μm is appropriate in terms of printability and firing characteristics. The aluminum powder preferably has a mass equal to or more than 50% and equal to or less than 90% of the gross mass of the conductive paste.

The conductive paste for electrodes includes the glass powder containing tellurium, lead, vanadium, boron, and the like in addition to the aluminum powder. The glass powder may contain a simple substance of a chemical element such as tellurium, lead, vanadium, boron, or the like, or may include metal particles or compound particles based on an alloy of these chemical elements. The glass powder may be produced by mixing, for example, a first glass frit based on PbO—B₂O₃ and a second glass frit based on TeO₂—V₂O₅ or may be produced by pulverizing the glass produced by mixing the above-mentioned components.

The mass of the glass powder content is preferably equal to or more than 0.01% and equal to or less than 5% of the gross mass of the conductive paste. The mass of the glass powder content is set to fall within this numerical range, thereby improving the electrical and mechanical contact between the silicon substrate and the electrodes and regulating the warpage of the substrate after the formation of electrodes.

The organic vehicle is obtained by dissolving an organic resin component (organic binder) used as a binder into an organic solvent. The organic binder may be cellulosic resin, acrylic resin, alkyd resin, or the like. The organic solvent may be terpineol, diethylene glycol monobutyl ether acetate, or the like.

Note that silicon powder, zinc powder, and the like may be added as accessory components of the conductive paste. Adding the proper amount of silicon powder and zinc powder would result in improvement associated with, for example, the warpage of the substrate, the resistance of the electrodes and the like after the formation of electrodes.

<Solar Cell Element>

The following describes the basic configuration of a solar cell element 10 according to the present embodiment. The solar cell element 10 has a back surface 1b being a first main surface and a front surface 1a being a second main surface opposed to the back surface 1b. The solar cell element 10 includes a silicon substrate 1 in which a p-type semiconductor region and an n-type semiconductor region are laminated in such a manner that, for example, the p-type semiconductor region is closest to the back surface 1b and the n-type semiconductor region is closest to the front surface 1a. The solar cell element 10 further includes an electrode disposed on the p-type semiconductor region of the silicon substrate 1.

In the above-mentioned electrode, the mass ratio of the glass component of the above-mentioned conductive paste is kept substantially constant. That is, the above-mentioned electrode includes a glass component containing at least vanadium oxide, tellurium oxide, and boron oxide. The glass component has a vanadium oxide content smaller than the sum of a tellurium oxide content and a boron oxide content. The glass component containing vanadium oxide, tellurium oxide, and boron oxide allows for the formation of a p-type electrode having excellent electrical characteristics regardless of the conditions of the back surface of the silicon substrate 1 associated with, for example, a texture and an anti-reflection layer formed on the back surface. The above-mentioned glass component also allows for the production of a solar cell element in which the electrodes have improved adhesion to the silicon substrate 1 while the warpage is small.

The above-mentioned electrode includes the glass component containing at least vanadium oxide, tellurium oxide, and boron oxide. The glass component may contain 5 to 33 parts by mass of vanadium oxide, 4 to 30 parts by mass of tellurium oxide, and 4 to 18 parts by mass of boron oxide based on 100 parts by mass of the glass component. The p-type electrode is formed through the use of the glass component mentioned above, allowing for the production of a solar cell element having excellent properties in which the warpage is small and the electrodes have improved adhesion to the silicon substrate 1.

Next, a specific example of the solar cell element 10 is described. The silicon substrate 1 may be a single-crystal silicon substrate or a polycrystalline silicon substrate of one conductivity type (for example, p type) including a predetermined dopant element. The silicon substrate 1 has a resistivity of about 0.2 to 2 Ω·cm. The silicon substrate 1 preferably has a thickness equal to or smaller than, for example, 250 μm, and more preferably has a thickness equal to or smaller than 150 μm. It is not required that the silicon substrate 1 has a particular shape. It is preferable that the silicon substrate 1 has a quadrilateral shape in plan view in terms of, for example, the manufacturing method and the reduction of the gap between a large number of solar cell elements arranged to form a solar cell module.

The following describes an example of the silicon substrate 1 being a p-type silicon substrate. For example, boron or gallium is preferably added as the dopant element such that the silicon substrate 1 has the p type.

A reverse-conductivity-type layer 3 that forms a p-n junction with an one-conductivity-type layer 2 is the layer of a conductivity type reverse to that of the one-conductivity-type layer 2 (silicon substrate 1) and is formed on the front surface 1a side of the silicon substrate 1. In a case where the one-conductivity-type layer 2 has the p-type conductivity, the reverse-conductivity-type layer 3 is formed so as to have the n-type conductivity. If the silicon substrate 1 has the p-type conductivity, the reverse-conductivity-type layer 3 can be formed through the diffusion of the dopant element, such as phosphorus, on the front surface 1a side of the silicon substrate 1.

An anti-reflection layer 4 reduces the reflectivity of light on the front surface 1a to increase the amount of light absorbed in the silicon substrate 1. The anti-reflection layer 4 increases electron-hole pairs generated due to the light absorption, thereby contributing the improvement in the conversion efficiency of the solar cell. The anti-reflection layer 4 may be, for example, a silicon nitride film, a titanium oxide film, a silicon oxide film, an aluminum oxide film, or a lamination film including these films. The refractive index and the thickness of the anti-reflection layer 4 are selected as appropriate depending on the constituent material and set in such a manner that the non-reflective conditions are provided for the relevant incident light. The anti-reflection layer 4 formed on the silicon substrate 1 preferably has a refractive index of about 1.8 to 2.3 and a thickness of about 500 to 1200 Å. The anti-reflection layer 4 also produces effects of a passivation film that reduces the deterioration of the conversion efficiency caused by the recombination of carriers at the interface and the grain boundary of the silicon substrate 1.

A BSF (Back-Surface-Field) region 7 has the function of forming an internal electric filed on the back surface 1b side of the silicon substrate 1 and reducing the deterioration in the conversion efficiency caused by the recombination of carriers in the vicinity of the back surface 1b. Although the BSF region 7 has the same conductivity type as that of the one-conductivity-type layer 2 of the silicon substrate 1, the BSF region 7 has a majority carrier concentration that is higher than the concentration of the majority carriers in the one-conductivity-type layer 2. This indicates that the dopant element in BSF region 7 is present in concentrations higher than the concentration of dopant element doped into the one-conductivity-type layer 2. Assuming that the silicon substrate 1 has the p-type, the BSF region 7 is preferably formed by, for example, diffusing the dopant element, such as boron or aluminum, on the back surface 1b side in such a manner that the concentration of the dopant element reaches around 1×10¹⁸ to 5×10²¹ atoms/cm³.

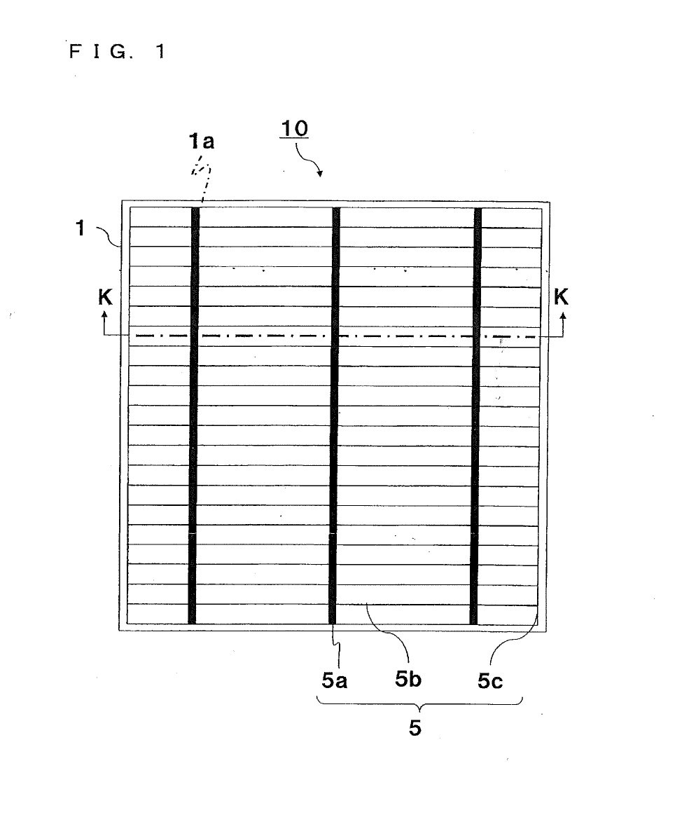

As shown in FIG. 1, a front-surface electrode 5 includes front-surface output extracting electrodes (bus bar electrodes) 5a and front-surface collecting electrodes (finger electrodes) 5b. At least a part of the front-surface output extracting electrode 5a intersects the front-surface collecting electrodes 5b. The front-surface output extracting electrodes 5a each have a width of about, for example, 1 to 3 mm.

The front-surface collecting electrodes 5b each have a line width of about 50 to 200 μm, thus being finer than the front-surface output extracting electrodes 5a. The front-surface collecting electrodes 5b are formed at intervals of about 1.5 to 3 mm.

The front-surface electrode 5 has a thickness of about 10 to 40 μm. The front-surface electrode 5 can be formed, for example, in such a way that a silver paste made of silver powder, a glass frit, an organic vehicle, and the like, is applied by screen printing or the like to form a desired shape and then the silver paste is fired. In the formation of the front-surface electrode 5, the component of the glass frit fused during the firing of the silver paste causes the fusion of the anti-reflection layer 4, reacts with the outermost surface of the silicon substrate 1, and then adheres to the surface, whereby the front-surface electrode 5 is formed. The front-surface electrode 5 is electrically connected with the silicon substrate 1 and the mechanical adhesion of the front-surface electrode 5 to the silicon substrate 1 is maintained. The front-surface electrode 5 may include a primary electrode layer formed as described above and a plated electrode layer being a conductive layer formed on the primary electrode layer by plating.

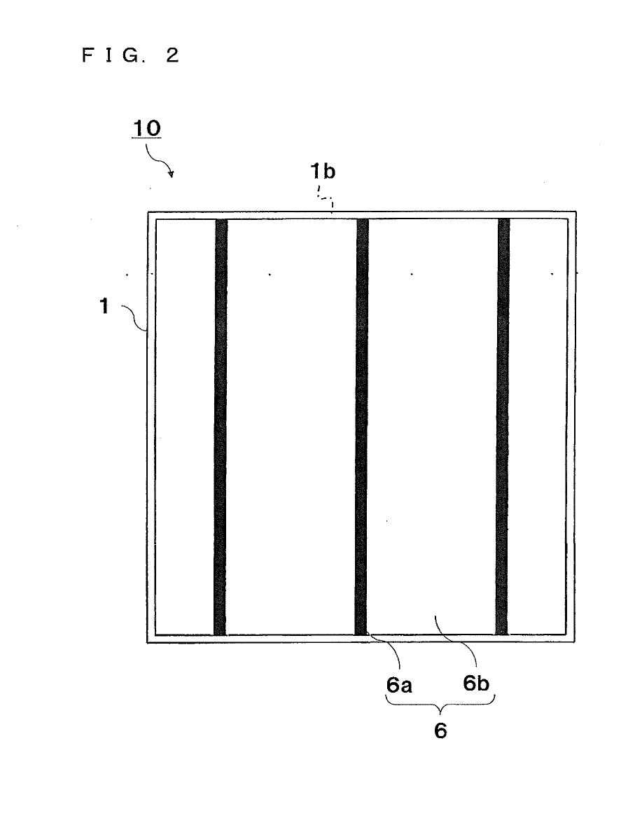

As shown in FIG. 2, a back-surface electrode 6 includes back-surface output extracting electrodes 6a and back-surface collecting electrodes 6b. The back-surface output extracting electrodes 6a according to the present embodiment each have a thickness of about 10 to 30 μm and a width of about 1.3 to 7 mm. The back-surface output extracting electrodes 6a can be formed, for example, in such a way that the above-mentioned silver paste is applied to form a desired shape and then the silver paste is fired. The back-surface collecting electrodes 6b each have a thickness of about 15 to 50 μm and are formed substantially all over the back surface 1b of the silicon substrate 1 except for a part of the back-surface output extracting electrodes 6a. The back-surface collecting electrodes 6b can be formed, for example, in such a way that an aluminum paste based on aluminum is applied to form a desired shape and then the aluminum paste is fired.

In the present embodiment, the aluminum paste includes a glass component containing at least vanadium oxide, tellurium oxide, and boron oxide as described above, and the glass component has a vanadium oxide content smaller than the sum of a tellurium oxide content and a boron oxide content. Alternatively, the aluminum paste includes a glass component containing at least vanadium oxide, tellurium oxide, and boron oxide, and the glass component contains 5 to 33 parts by mass of vanadium oxide, 4 to 30 parts by mass of tellurium oxide, and 4 to 18 parts by mass of boron oxide based on 100 parts by mass of the glass component. This provides the solar cell element 10 in which the back-surface collecting electrodes 6b have improved adhesion to the silicon substrate 1 while the warpage of the silicon substrate 1 after the formation of the back-surface collecting electrodes 6b is regulated. For example, TeO₂ being tellurium oxide contained in the aluminum paste forms a glass network, thereby contributing to the improvement in the mechanical strength of the back-surface collecting electrodes 6b. Further, TeO₂ has higher reactivity than that of PbO being lead oxide, and thus, in the presence of a nitride film made of Si₃N₄ or the like or an oxide film made of SiO₂ or the like on the surface coated with the paste, the aluminum paste easily fires-through while being fired (easily reacts with the nitride film and the oxide film and easily melts down the nitride film and the oxide film), providing excellent contact between the silicon substrate 1 and the back-surface collecting electrodes 6b.

In the example described in the present embodiment, tellurium is contained in the aluminum paste as an oxide. It is known that tellurium by itself has a low melting point of about 450° C., and thus adding tellurium as tellurium powder in the aluminum paste is expected to produce the similar effects. Meanwhile, V₂O₅ being a vanadium oxide contributes to the stabilization of electrodes, especially to the improvement in moisture resistance and water resistance. Boron (B) contained in B₂O₃ being a boron oxide functions as an acceptor (p-type dopant) while diffusing in the silicon substrate 1, thereby reducing the contact resistance especially in the formation of electrodes on the p-type silicon region.

The aluminum paste used to form the back-surface collecting electrodes 6b in the present embodiment is based on aluminum and also contains tellurium, lead, vanadium, boron, and the like. This allows the solar cell element 10 to maintain the high conversion efficiency and regulates an increase in the warpage of the substrate after the formation of electrodes. Further, this can provide the solar cell element 10 in which the back-surface collecting electrodes 6b have improved adhesion to the silicon substrate 1. Boron and vanadium are preferably contained as the electrode component in order to achieve excellence in the mechanical strength, the moisture resistance, and the electrical characteristics of the electrodes. In particular, the aluminum paste includes the first glass frit based on PbO—B₂O₃ and the second glass frit based on TeO₂—V₂O₅ having a low glass softening point, so that glass frit spreads well while the electrodes are fired, and the adhesion of the electrodes is accordingly improved.

The constituent components of the solar cell element 10 are identified in such a way that the cut surface of the solar cell element is firstly observed with a scanning electron microscope (SEM) or the like to discriminate between the region made of a metal component and a region made of a glass component. Then, the composition of each region can be examined with an analytical method such as the electron probe micro-analyser (EPMA), the scanning electron microscope-energy dispersive X-ray detector (SEM-EDX), the Auger electron spectroscopy (AES), the secondary ion mass spectrometry (SIMS), the X-ray photoelectron spectroscopy (XPS), or the like. It has been confirmed that the glass component of the aluminum paste in the electrodes remains virtually unchanged and remains substantially the same after the firing.

In the region made of the glass component, the chemical elements such as tellurium, vanadium, lead, and boron are present as oxides such as TeO₂, V₂O₅, PbO, B₂O₃. Although the oxidization number of each of the chemical elements is not constant in a part of the region made of the glass component in some cases, the composition is obtained through conversions, for convenience, based on the assumption that the chemical elements are present as oxides in accordance with stoichiometry in the present embodiment.

<Method for Manufacturing Solar Cell Element>

The following describes a method for manufacturing the solar cell element 10. As described above, the solar cell element 10 includes the silicon substrate 1 being a semiconductor substrate, the anti-reflection layer 4 disposed in a first region on one main surface of the silicon substrate 1, and the electrode that is disposed in a second region on the one main surface of the silicon substrate 1 and formed by firing the above-mentioned conductive paste. The manufacturing of the solar cell element 10 having the above configuration includes a first step of forming the anti-reflection layer 4 on the main surface of the silicon substrate 1, a second step of disposing the above-mentioned conductive paste on the anti-reflection layer 4, and a third step of disposing the anti-reflection layer 4 in the first region of the silicon substrate 1 and forming the electrode in the second region of the silicon substrate 1 by firing the above-mentioned conductive paste and removing the anti-reflection layer 4 located below the conductive paste.

The following specifically describes the method for manufacturing the solar cell element 10. Firstly, the silicon substrate 1 for constituting the one-conductivity-type layer 2 is prepared. The silicon substrate 1 being a single-crystal silicon substrate is formed by, for example, the float zone (FZ) method or the Czochralski (CZ) method. The silicon substrate 1 being a polycrystalline silicon substrate is formed by, for example, casting. The following description will be given assuming that a p-type polycrystalline silicon is used.

Firstly, a polycrystalline silicon ingot is produced by, for example, casting. Subsequently, the ingot is sliced into a thickness of, for example, 250 μm or less, whereby the silicon substrate 1 is produced. Then, the surface of the silicon substrate 1 is desirably etched slightly with an aqueous solution of NaOH, KOH, or fluoro-nitric acid, or the like in order to remove a mechanically damaged layer and a contaminated layer of the cut surface thereof. After the step of etching, a structure (texture) including minute irregularities is desirably formed in the surface of the silicon substrate 1 by wet etching or dry etching. The reflectivity of light on the front surface 1a is reduced due to the formation of the texture, so that the conversion efficiency of the solar cell is improved. According to a particular method for forming the texture, the above-mentioned step of removing the mechanically damaged layer can be omitted.

Next, the reverse-conductivity-type layer 3 of n type is formed in the surface layer on the front surface 1a side of the silicon substrate 1. The reverse-conductivity-type layer 3 is formed by, for example, the coating thermal diffusion method in which P₂O₅ in a paste state is applied to the surface of the silicon substrate 1 and is thermally diffused, the vapor-phase thermal diffusion method using phosphorus oxychloride (POCl₃) in gas state as a diffusion source, or the ion implantation method in which phosphorus ions are directly diffused. The reverse-conductivity-type layer 3 is formed so as to have a thickness of about 0.1 to 1 μm and a sheet resistance of about 40 to 150Ω/□. The method for forming the reverse-conductivity-type layer 3 is not limited to the above-mentioned method. For example, the thin film forming technique may be used to form a hydrogenated amorphous silicon film or a crystalline silicon film including a microcrystalline silicon film. Further, an i-type silicon region may also be formed between the silicon substrate 1 and the reverse-conductivity-type layer 3.

In a case where the formation of the reverse-conductivity-type layer 3 is accompanied by the formation of the reverse-conductivity-type layer on the back surface 1b side, only the reverse-conductivity-type layer on the back surface 1b side is etched to be removed, whereby the p-type conductivity region is exposed. For example, only the back surface 1b side of the silicon substrate 1 is immersed in the fluoro-nitric acid solution to remove the reverse-conductivity-type layer 3. Then, a phosphorus glass that has adhered to the surface of the silicon substrate 1 in the formation of the reverse-conductivity-type layer 3 is etched to be removed. The similar structure can be formed through the processes of: forming a diffusion mask on the back surface 1b side in advance; forming the reverse-conductivity-type layer 3 by the vapor-phase thermal diffusion method or the like; and subsequently removing the diffusion mask.

Consequently, the silicon substrate 1 including the one-conductivity-type layer 2 and the reverse-conductivity-type layer 3 can be prepared.

Next, the anti-reflection layer 4 being an anti-reflection film is formed. In the formation of the anti-reflection layer 4, a film made of silicon nitride, titanium oxide, silicon oxide, aluminum oxide, or the like is formed by the plasma enhanced chemical vapor deposition (PECVD) method, the thermal CVD method, the vapor deposition method, the sputtering method, or the like. For example, in the formation of the anti-reflection layer 4 made of a silicon nitride film by the PECVD method, with the temperature inside the reaction chamber being set at about 500° C., a mixed gas containing silane (SiH₄) and ammonia (NH₃) is diluted with nitrogen (N₂) and is then turned into a plasma by the glow discharge decomposition, so that the anti-reflection layer 4 is formed by deposition.

Next, the BSF region 7 is formed on the back surface 1b side of the silicon substrate 1. For example, the BSF region 7 may be formed by the thermal diffusion method using boron tribromide (BBr₃) as the diffusion source at a temperature of about 800 to 1100° C. or may be formed by applying an aluminum paste using the printing method and then firing the aluminum paste at a temperature of about 600 to 850° C. to diffuse aluminum in the silicon substrate 1. The method for printing and firing the aluminum paste allows for the formation of a desired diffusion region only on the printing surface. Further, the p-n isolation (isolating the continuous region in the p-n junction portion) can be performed by the application of lasers or the like only to the peripheral portion on the back surface 1b side without removing another n-type reverse-conductivity-type layer that has been formed on the back surface 1b side during the formation of the reverse-conductivity-type layer 3. The method for forming the BSF region 7 is not limited to the above method. For example, a hydrogenated amorphous silicon film, a crystalline silicon film including a microcrystalline silicon film, or the like may be formed using the thin film technique. Further, an i-type silicon region may be formed between the one-conductivity-type layer 2 and the BSF region 7.

Next, the front-surface electrode 5 and the back-surface electrode 6 are formed. The front-surface electrode 5 is produced using a conductive paste containing a conductive component based on silver, a glass frit, and an organic vehicle. The front surface 1a of the silicon substrate 1 is coated with the conductive paste. Then, firing is performed at a maximum temperature of 600 to 850° C. for about several tens of seconds to several tens of minutes, so that the front-surface electrode 5 is formed on the silicon substrate 1. The coating method may be, for example, the screen printing. After the coating, a solvent is preferably evaporated at a predetermined temperature for drying. In the firing process, the glass frit and the anti-reflection layer 4 react with each other at a high temperature due to the fire through, whereby the front-surface electrode 5 is electrically and mechanically connected with the silicon substrate 1. The front-surface electrode 5 may include a primary electrode layer formed as described above and a plated electrode layer formed on the primary electrode layer by plating.

The back-surface collecting electrode 6b is produced using an aluminum paste including a glass component, aluminum-based powder, and an organic vehicle, the glass component containing, for example, at least vanadium oxide, tellurium oxide, and boron oxide, the glass component having a vanadium oxide content smaller than the sum of a tellurium oxide content and a boron oxide content. Alternatively, the back-surface collecting electrode 6b is produced using an aluminum paste including a glass component, aluminum-based powder, and an organic vehicle, the glass component containing vanadium oxide, tellurium oxide, and boron oxide, the glass component containing 5 to 33 parts by mass of vanadium oxide, 4 to 30 parts by mass of tellurium oxide, and 4 to 18 parts by mass of boron oxide based on 100 parts by mass of the glass component. The aluminum paste is applied substantially all over the back surface 1b except for a part of the portion on which the back-surface output extracting electrode 6a is going to be formed. The coating method may be, for example, the screen printing. It is preferable that an aluminum paste is applied and then a solvent is evaporated at a predetermined temperature for drying because the aluminum paste is less likely to adhere to the other part during execution of work.

The aluminum paste used in the present embodiment contains, for example, tellurium, vanadium, and boron as described above, thus providing the solar cell element 10 in which the electrodes have improved adhesion to the silicon substrate 1 while an increase in the warpage of the substrate after the formation of electrodes is prevented.

The back-surface output extracting electrode 6a is produced using a silver paste containing metal powder based on silver, a glass frit, and an organic vehicle. The silver paste is applied so as to form a predetermined shape. The position that is in contact with a part of the aluminum paste is coated with the silver paste, so that the back-surface output extracting electrode 6a and the back-surface collecting electrode 6b partially overlap one another, thereby forming the electrical contact. The coating method may be, for example, the screen printing. After the coating, a solvent is preferably evaporated at a predetermined temperature for drying.

Then, the silicon substrate 1 is fired in the firing chamber at a maximum temperature of 600 to 850° C. for about several tens of seconds to several tens of minutes, so that the back-surface electrode 6 is formed on the back surface 1b side of the silicon substrate 1. Either the back-surface output extracting electrode 6a or the back-surface collecting electrode 6b may be coated ahead of the other. Both of the electrodes may be fired at the same time. Alternatively, one of two electrodes may be coated and fired first, and subsequently the other one may be coated and fired.

In particular, the aluminum paste is used in a case where the back-surface output extracting electrode 6a is coated and fired after the back-surface collecting electrode 6b is coated and fired. This can keep the flatness of the surface of the back-surface collecting electrode 6b while increasing the adhesion (peel strength) of the back-surface output extracting electrode 6a and the back-surface collecting electrode 6b, thus being preferable for the formation of the desired shape during the printing of the back-surface output extracting electrode 6a.

Although the texture of the surface of the silicon substrate 1 is formed on the front surface 1a being the light receiving surface as described above, the texture may be formed on the back surface 1b as well according to a particular method. In particular, the mechanical strength of the electrode is likely to deteriorate if the irregularities of the texture each have a width smaller than the diameter of the aluminum particle in the electrode. Thus, the conductive paste and the electrodes in the present embodiment are particularly effective.

The nitride film or the oxide film used as the anti-reflection layer 4 is formed on the front surface 1a being the light receiving surface of the silicon substrate 1. For reasons of the manufacturing method, in some cases, the film extends to the back surface 1b, and consequently the film is formed in the region of the end portion of the back surface 1b. The conductive paste used in the present embodiment is preferable because it can fire-through such a film during firing to form the back-surface electrode 6.

### Other Embodiments

The present invention is not limited to the above-mentioned embodiment, and numerous modifications and changes thereof can be devised without departing from the scope of the invention.

For example, a passivation film may be formed on the back surface 1b side of the silicon substrate 1. The passivation film has the function of reducing the recombination of carriers in the back surface 1b of the silicon substrate 1. Silicon nitride, silicon oxide, titanium oxide, aluminum oxide, or the like can be used as the passivation film. The passivation film may be formed so as to have a thickness of about 100 to 2000 Å by, for example, the PECVD method, the thermal CVD method, the vapor deposition method, or the sputtering method. Thus, the structure of the back surface 1b side of the silicon substrate 1 may be the structure of the back surface 1b side for use in the passivated emitter and rear cell (PERC) structure or the passivated emitter rear locally-diffused (PERL) structure. The conductive paste according to the present embodiment can be preferably used for the step of forming electrodes by applying the conductive paste on the rear-surface passivation film and firing the conductive paste.

Auxiliary electrodes 5c each having a liner shape that intersect the front-surface collecting electrodes 5b may be formed on both of the end portions that intersect the longitudinal direction of the front-surface collecting electrodes 5b. Thus, in the event of the breakage of some of the front-surface collecting electrodes 5b, an increase in resistance can be reduced and a current can be caused to flow into the front-surface output extracting electrodes 5a through the remaining front-surface collecting electrodes 5b.

Similarly to the front-surface electrodes 5, the back-surface electrode 6 may have a shape including the back-surface output extracting electrodes 6a and the liner back-surface collecting electrodes 6b that intersect the back-surface output extracting electrodes 6a, and the back-surface electrode 6 may be formed of a primary electrode layer and a plated electrode layer.

At the formation position for forming the front-surface electrode 5 on the silicon substrate 1, a region (a selective emitter region) that has the same conductivity type as the reverse-conductivity-type layer 3 and has a dopant concentration higher than that of the reverse-conductivity-type layer 3 may formed. At this time, the selective emitter region is formed so as to have a sheet resistance lower than that of the reverse-conductivity-type layer 3. The selective emitter region is formed so as to have a lower sheet resistance, whereby the contact resistance between the selective emitter region and the electrodes can be reduced. The selective emitter region can be formed in the following manner. For example, the reverse-conductivity-type layer 3 is formed by the coating thermal diffusion method or the vapor-phase thermal diffusion method, and then the silicon substrate 1 is irradiated with a laser in accordance with the electrode shape of the front-surface electrode 5 while the phosphorus glass is left. Consequently, phosphorus is diffused from the phosphorus glass into the reverse-conductivity-type layer 3, thereby forming the selective emitter region.

In the above-mentioned embodiment, the description has been given on the example of using the p-type silicon substrate as the silicon substrate 1, which is not limited thereto. For example, the solar cell element 10 can be produced using the n-type silicon substrate. In a case where the n-type silicon substrate is used as the silicon substrate 1, the one-conductivity-type layer 2 has the n type conductivity and the reverse-conductivity-type layer 3 has the p type conductivity. The dopant for the one-conductivity-type layer 2 of n type may be, for example, phosphorus or arsenic, and the dopant for the reverse-conductivity-type layer 3 of p type may be, for example, boron or aluminum. As the front-surface electrode 5, the aluminum-based electrode that includes the glass component containing a tellurium oxide, a lead oxide, a vanadium oxide, and a boron oxide is formed. This provides the solar cell element in which high conversion efficiency is maintained, an increase in the warpage of the substrate after the formation of electrodes is prevented, and the electrodes have improved adhesion to the substrate.

### Examples

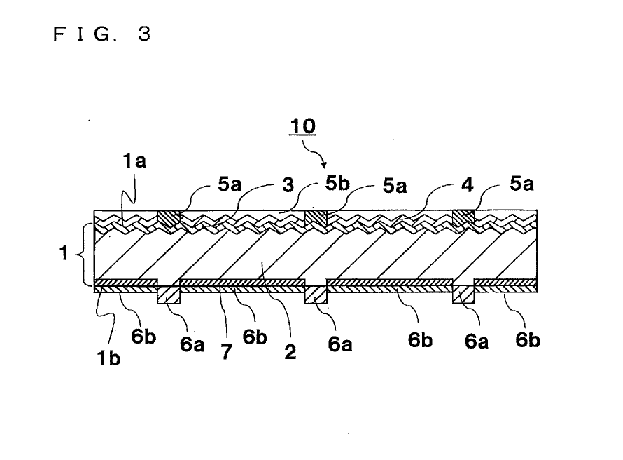

The following describes examples. The description will be given with reference to FIGS. 1 to 3.

Firstly, a single-crystal silicon substrate 1 having a square shape of side 156 mm in plan view, a thickness of about 200 μm, and a resistivity of about 1.5 Ω·cm was prepared.

Next, a texture was formed on the front surface 1a of the silicon substrate 1 by wet etching using an etching solution obtained by adding 2-propanyl to a NaOH aqueous solution.

Then, a reverse-conductivity-type layer 3 was formed by the vapor-phase thermal diffusion method using POCl₃ as the diffusion source. The phosphorus glass generated at that time was removed by etching using a hydrofluoric acid solution. Further, the p-n isolation was performed using laser beams. The reverse-conductivity-type layer 3 had a sheet resistance of about 70 Ω/□.

Then, a silicon nitride film which was to be an anti-reflection layer 4 was formed on the front surface 1a of the silicon substrate 1 by the PECVD method. At this time, a part of the silicon nitride film was formed so as to extend to the end portion of a back surface 1b of the silicon substrate 1.

Then, an aluminum paste was applied substantially all over the back surface 1b of the silicon substrate 1 and was fired, thereby forming a BSF region 7 and back-surface collecting electrodes 6b. The front surface 1a and the back surface 1b of the silicon substrate 1 were respectively coated with a silver paste, which was subsequently fired to form a front-surface electrode 5 and back-surface output extracting electrodes 6a.

The back-surface collecting electrodes 6b were formed as described below. Firstly, aluminum pastes were produced by mixing, aluminum powder, glass frits denoted by GF-A to GF-D including the components shown in Table 1, an organic vehicle, and the like in such a manner that the aluminum pastes have the ratios of components on conditions 1 to 11 shown in Table 2.

As shown in Table 1, the glass frit GF-A contains 20 parts by mass of B₂O₃, 80 parts by mass of PbO, and substantially no other components. The glass frit GF-B contains 45 parts by mass of V₂O₅ and 40 parts by mass of TeO₂, and further contains 15 parts by mass of other components. The glass frit GF-C contains 46 parts by mass of V₂O₅ and 36 parts by mass of TeO₂, and further contains 18 parts by mass of other components. The glass frit GF-D contains 14 parts by mass of B₂O₃, 44 parts by mass of SiO₂, 25 parts by mass of Bi₂O₃, and 17 parts by mass of other components.

TABLE 1

| | | component composition ratio (parts by mass) | | | | | | |
|---|---|---|---|---|---|---|---|---|
| | | V₂O₅ | TeO₂ | B₂O₃ | PbO | SiO₂ | Bi₂O₃ | other |
| glass | GF-A | — | — | 20 | 80 | — | — | 0 |
| frit | GF-B | 45 | 40 | — | — | — | — | 15 |
| | GF-C | 46 | 36 | — | — | — | — | 18 |
| | GF-D | — | — | 14 | — | 44 | 25 | 17 |

TABLE 2

| | component mixture ratio of paste (parts by mass) | | | | |
|---|---|---|---|---|---|
| | Al powder | GF-A | GF-B | GF-C | GF-D |
| condition 1 | 100 | 0.26 | — | — | — |
| condition 2 | 100 | 0.26 | 0.03 | — | — |
| condition 3 | 100 | 0.26 | 0.15 | — | — |
| condition 4 | 100 | 0.26 | 0.45 | — | — |
| condition 5 | 100 | 0.26 | 0.75 | — | — |
| condition 6 | 100 | 0.26 | 1.5 | — | — |
| condition 7 | 100 | 0.26 | — | 0.15 | — |
| condition 8 | 100 | 0.26 | — | 0.45 | — |
| condition 9 | 100 | 0.26 | 0.08 | 0.08 | — |
| condition 10 | 100 | 0.13 | 0.75 | — | 0.13 |
| condition 11 | 100 | — | 0.75 | — | 0.26 |

As shown in Table 2, on the condition 1, an aluminum paste was produced by mixing 100 parts by mass of aluminum powder, 0.26 parts by mass of the glass frit GF-A, an organic vehicle, and the like. On the conditions 2 to 6, an aluminum paste was produced by mixing 100 parts by mass of aluminum powder, 0.26 parts by mass of the glass frit GF-A, 0.03 to 1.5 parts by mass of the glass frit GF-B, an organic vehicle, and the like. On the conditions 7 and 8, an aluminum paste was produced by mixing 100 parts by mass of aluminum powder, 0.26 parts by mass of the glass frit GF-A, 0.15 to 0.45 parts by mass of the glass frit GF-C, an organic vehicle, and the like. On the condition 9, an aluminum paste was produced by mixing 100 parts by mass of aluminum powder, 0.26 parts by mass of the glass frit GF-A, 0.08 parts by mass of the glass frit GF-B, 0.08 parts by mass of the glass frit GF-C, an organic vehicle, and the like. On the condition 10, an aluminum paste was produced by mixing 100 parts by mass of aluminum powder, 0.13 parts by mass of the glass frit GF-A, 0.75 parts by mass of the glass frit GF-B, 0.13 parts by mass of the glass frit GF-D, an organic vehicle, and the like. On the condition 11, an aluminum paste was produced by mixing 100 parts by mass of aluminum powder, 0.75 parts by mass of the glass frit GF-B, 0.26 parts by mass of the glass frit GF-D, an organic vehicle, and the like.

The values of the main glass components shown in Table 1 are the mass ratios of the metal oxide components contained in the glass frit based on 100 parts by mass of the glass frit. The mass ratios were obtained through conversions assuming that all of the metal oxides in the glass component were present as specific oxides each having the stoichiometric composition, which holds true for the following description. That is, the conversion was performed assuming that all of the oxides of vanadium (vanadium oxides) were present as V₂O₅. The conversion was performed assuming that all of the oxides of tellurium (tellurium oxides) were present as TeO₂. The conversion was performed assuming that all of the oxides of boron (boron oxides) were present as B₂O₃. The conversion was performed assuming that all of the oxides of lead (lead oxides) were present as PbO. The conversion was performed assuming that all of the oxides of silicon were present as SiO₂. The conversion was performed assuming that all of the oxides of bismuth were present as Bi₂O₃.

Then, the back surface 1b of the individual silicon substrate 1 was coated with the corresponding one of these aluminum pastes by screen printing. With reference to Table 1, “other” components of the glass frits GF-B, GF-C, and GF-D refer to P₂O₅, ZnO, BaO, Ag₂O, and the like, which were secondarily added.

Then, the aluminum paste was fired for 3 minutes in such a manner that the peak temperature of the silicon substrate 1 reaches about 800° C., whereby the back-surface collecting electrode 6b was formed on the silicon substrate 1. Table 3 shows the components of the formed back-surface collecting electrode 6b.

TABLE 3

| | electrode component composition ratio (parts by mass) | | | | |
|---|---|---|---|---|---|
| | Al | V₂O₅ | TeO₂ | B₂O₃ | PbO |
| condition 1 | 100 | 0.00 | 0.00 | 0.05 | 0.21 |
| condition 2 | 100 | 0.01 | 0.01 | 0.05 | 0.21 |
| condition 3 | 100 | 0.07 | 0.06 | 0.05 | 0.21 |
| condition 4 | 100 | 0.20 | 0.18 | 0.05 | 0.21 |
| condition 5 | 100 | 0.34 | 0.30 | 0.05 | 0.21 |
| condition 6 | 100 | 0.68 | 0.60 | 0.05 | 0.21 |
| condition 7 | 100 | 0.07 | 0.05 | 0.05 | 0.21 |
| condition 8 | 100 | 0.21 | 0.16 | 0.05 | 0.21 |
| condition 9 | 100 | 0.07 | 0.06 | 0.05 | 0.21 |
| condition 10 | 100 | 0.34 | 0.30 | 0.04 | 0.10 |
| condition 11 | 100 | 0.34 | 0.30 | 0.04 | 0.00 |

Table 3 shows the component composition ratios of the produced electrode and indicates the amounts of vanadium oxide, tellurium oxide, boron oxide, and lead oxide that were present based on 100 parts by mass of aluminum. As described above, the conversion was performed with respect to, for example, vanadium assuming that all of the vanadium oxides were present as V₂O₅ having the stoichiometric composition. Similarly, the conversions were performed assuming that other oxides were present as the oxides shown in Table 3.

Then, the photoelectric conversion efficiency of the produced solar cell element 10 and the warpage of the silicon substrate 1 were measured, and exfoliation tests (peel tests) were performed to evaluate the adhesion of the back-surface collecting electrode 6b to the silicon substrate 1. Together with the glass component composition ratios of the back-surface collecting electrode 6b, the results of the peel tests are shown in Table 4. The glass component composition ratios in Table 4 indicate the mass ratios of the respective glass components based on 100 parts by mass of the entire glass component.

TABLE 4

| | | | | | | results of peel | |
|---|---|---|---|---|---|---|---|
| | glass component composition | | | | | tests | |
| | ratio (parts by mass) | | | | | end | inner |
| | V₂O₅ | TeO₂ | B₂O₃ | PbO | other | portion | surface |
| condition 1 | 0 | 0 | 20 | 80 | 0 | 0 | 2 |
| condition 2 | 5 | 4 | 18 | 72 | 2 | 1 | 2 |
| condition 3 | 16 | 15 | 13 | 51 | 5 | 2 | 3 |
| condition 4 | 29 | 25 | 7 | 29 | 10 | 2 | 3 |
| condition 5 | 33 | 30 | 5 | 21 | 11 | 3 | 1 |
| condition 6 | 38 | 34 | 3 | 12 | 13 | 3 | 0 |
| condition 7 | 17 | 13 | 13 | 51 | 7 | 2 | 3 |
| condition 8 | 29 | 23 | 7 | 29 | 11 | 3 | 2 |
| condition 9 | 17 | 14 | 13 | 51 | 6 | 2 | 3 |
| condition 10 | 33 | 30 | 4 | 10 | 22 | 2 | 1 |
| condition 11 | 33 | 30 | 4 | 0 | 33 | 1 | 1 |

The photoelectric conversion efficiency was measured in accordance with the conditions of Japanese Industrial Standards (JIS) C 8913 at an air mass (AM) of 1.5 and an irradiation of 100 mW/cm². As a result, it has been shown that the photoelectric conversion efficiency higher than that of the condition 1 is maintained on each of the conditions 2 to 11.

For the measurement of the warpage of the silicon substrate 1, the silicon substrate 1 was mounted on a horizontal table with the front surface 1a of the silicon substrate 1 pointing downward, and the distance in the vertical direction between the horizontal plane including the bottom of the front surface 1a and the horizontal plane including the top of the back surface 1b was measured. As a result, a warpage of 2.0 to 2.7 mm was observed on each of the conditions 1 to 11, indicating that there were no major changes in warpage relative to the condition 1. Note that a warpage equal to or smaller than 2.1 mm, which was smaller than the warpage observed on the condition 1, was observed on the conditions 2 and 3.

Thus, it has been shown that no large increase in warpage was observed in a case where the back-surface collecting electrode 6b included the glass component containing 5 to 33 parts by mass of vanadium oxide based on 100 parts by mass of the glass component as in the present embodiment.

In the peel tests, three types of evaluation tapes, each having different adhesion, were attached to the back-surface collecting electrodes 6b in the peripheral portion (end portion) and the central portion of the inner surface of the solar cell element, and then the tapes were pulled at a predetermined speed in the direction perpendicular to the attachment surface, whereby the peeled point and the peel strength were evaluated. With reference to FIG. 4, the “end portion” is the portion defined as the region within a distance equal to or smaller than 3 mm from the end of the solar cell element 10 and the “inner surface” is the portion defined as the region other than the “end portion.”

The ranking of the adhesiveness of the adhesive tapes used for evaluation in the peel tests, from lowest to highest, was a tape 1, a tape 2, and a tape 3. The tape 1 of the lowest adhesiveness had an adhesiveness of about 1.2 N/cm. The results of the peel tests were evaluated in four levels on a scale of 0 to 3. The level “3” in Table 4 indicates that no exfoliation has been visually observed for each tape. If this is the case, minor variations in the processing would not result in electrode exfoliation. At the level “2” in Table 4, no electrode exfoliation is visually observed for the tapes up to the tape 2, indicating that the electrode satisfies the adhesiveness requirement in the mass production of solar cell elements. At the level “1” in Table 4, no electrode exfoliation is visually observed for the tape 1, indicating the lower limit of the electrode adhesion test where the electrode is not defective. Meanwhile, the level “0” in Table 4 indicates the electrode exfoliation has been observed for the tape 1 and thus the electrode is defective.

As shown in Table 4, in a case where the glass component of the back-surface collecting electrode 6b contained a vanadium oxide component smaller than the sum of a tellurium oxide component and a boron oxide component (on the conditions 2 to 5 and the conditions 7 to 11), no electrode exfoliation was observed (the level was equal to or greater than “1”), producing excellent results in the peel tests.

On the conditions 2 to 5 and the conditions 7 to 11 that the glass component of the back-surface collecting electrode 6b contained 4 to 18 parts by mass of boron oxide based on 100 parts by mass of the glass component, no electrode exfoliation was observed (the level was equal to or greater than “1”), producing excellent results in the peel tests.

On the conditions 2 to 5 and the conditions 7 to 11 that the back-surface collecting electrode 6b included the glass component containing vanadium oxide, tellurium oxide, and boron oxide and that the glass component contained 5 to 33 parts by mass of vanadium oxide, 4 to 30 parts by mass of tellurium oxide, and 4 to 18 parts by mass of boron oxide based on 100 parts by mass of the glass component, no electrode exfoliation was observed (the level was equal to or greater than “1”), producing excellent results in the peel tests.

On the conditions 2 to 5 and the conditions 7 to 10 that the glass component of the back-surface collecting electrode 6b contained 10 to 72 parts by mass of lead oxide based on the 100 parts by mass of the glass component, no electrode exfoliation was observed (the level was equal to or greater than “1”), producing excellent results in the peel tests. No electrode exfoliation was observed on condition that lead oxide was virtually absent (condition 11). The exfoliation occurred at the end portion due to the glass component having an excessive lead oxide content. On the basis of these results, a vanadium oxide content, a tellurium oxide content, and a boron oxide content of the glass component, in particular, are presumed to have considerable influence on the results of the peel tests.

On the conditions 3 and 4 and the conditions 7 to 9 that the back-surface collecting electrode 6b included the glass component containing vanadium oxide, tellurium oxide, and boron oxide and that the glass component contained 16 to 29 parts by mass of vanadium oxide, 13 to 25 parts by mass of tellurium oxide, and 7 to 13 parts by mass of boron oxide based on 100 parts by mass of the glass component, excellent adhesion of the electrode was observed (the level was equal to or greater than “2”), producing extremely excellent results in the peel tests.

With reference to Table 4, on the conditions 2 to 5 and the conditions 7 to 11 that the back-surface collecting electrode 6b included at least 0.01 to 0.34 parts by mass of vanadium oxide or 0.01 to 0.30 parts by mass of tellurium oxide based on 100 parts by mass of aluminum, no electrode exfoliation was observed (the level was equal to or greater than “1”), producing excellent results in the peel tests.

The above-mentioned results have shown the effects produced on condition that the back-surface collecting electrode 6b includes a glass component containing at least vanadium oxide, tellurium oxide, and boron oxide and that the glass component has a vanadium oxide content smaller than the sum of a tellurium oxide content and a boron oxide content.

Similarly, the results have shown the effects obtained on condition that back-surface collecting electrode 6b includes a glass component containing at least vanadium oxide, tellurium oxide, and boron oxide and that the glass component contains 5 to 33 parts by mass of vanadium oxide, 4 to 30 parts by mass of tellurium oxide, and 4 to 18 parts by mass of boron oxide based on 100 parts by mass of the glass component.

### EXPLANATION OF REFERENCE SIGNS

1: silicon substrate
1a: front surface
1b: back surface
2: first semiconductor layer
3: second semiconductor layer
4: anti-reflection layer
5: front-surface electrode
5a: front-surface output extracting electrode
5b: front-surface collecting electrode
5c: auxiliary electrode
6: back-surface electrode
6a: back-surface output extracting electrode
6b: back-surface collecting electrode
7: BSF region
10: solar cell element

1. A solar cell element comprising:
a silicon substrate including a p-type semiconductor region in a surface thereof; and
an electrode that is located on the p-type semiconductor region and based on aluminum,
wherein the electrode includes a glass component containing vanadium oxide, tellurium oxide, and boron oxide, the glass component having a vanadium oxide content smaller than a sum of a tellurium oxide content and a boron oxide content.

2. The solar cell element according to claim 1, wherein the glass component of the electrode contains 4 to 18 parts by mass of boron oxide based on 100 parts by mass of the glass component.

3. A solar cell element comprising:
a silicon substrate including a p-type semiconductor region in a surface thereof; and
an electrode that is located on the p-type semiconductor region and based on aluminum,
wherein the electrode includes a glass component containing vanadium oxide, tellurium oxide, and boron oxide, the glass component containing 5 to 33 parts by mass of vanadium oxide, 4 to 30 parts by mass of tellurium oxide, and 4 to 18 parts by mass of boron oxide based on 100 parts by mass of the glass component.

4. The solar cell element according to claim 1, wherein the glass component of the electrode contains 16 to 29 parts by mass of vanadium oxide, 13 to 25 parts by mass of tellurium oxide, and 7 to 13 parts by mass of boron oxide based on 100 parts by mass of the glass component.

5. The solar cell element according to claim 1, wherein the glass component of the electrode further contains lead oxide, the glass component containing 10 to 72 parts by mass of lead oxide based on 100 parts by mass of the glass component containing lead oxide.

6. The solar cell element according to claim 1, wherein the electrode contains 0.01 to 0.34 parts by mass of vanadium oxide or 0.01 to 0.30 parts by mass of tellurium oxide based on 100 parts by mass of aluminum.

7. A method for manufacturing a solar cell element, the solar cell element including a silicon substrate that includes a p-type semiconductor region in a surface thereof and an electrode that is located on the p-type semiconductor region and based on aluminum,
the method comprising:
printing a conductive paste on the p-type semiconductor region of the silicon substrate, the conductive paste including a glass component, aluminum-based powder, and an organic vehicle, the glass component containing vanadium oxide, tellurium oxide, and boron oxide, the glass component having a vanadium oxide content smaller than a sum of a tellurium oxide content and a boron oxide content; and
forming the electrode on the p-type semiconductor region of the silicon substrate by firing the conductive paste.

8. A method for manufacturing a solar cell element, the solar cell element including a silicon substrate that includes a p-type semiconductor region in a surface thereof and an electrode that is located on the p-type semiconductor region and based on aluminum,
the method comprising:
printing a conductive paste on the p-type semiconductor region of the silicon substrate, the conductive paste including a glass component, aluminum-based powder, and an organic vehicle, the glass component containing vanadium oxide, tellurium oxide, and boron oxide, the glass component containing 5 to 33 parts by mass of vanadium oxide, 4 to 30 parts by mass of tellurium oxide, and 4 to 18 parts by mass of boron oxide based on 100 parts by mass of the glass component; and
forming the electrode on the p-type semiconductor region of the silicon substrate by firing the conductive paste.
